(19) United States
(12) Patent Application Publication
(10) Pub. No.: US 2023/0411933 A1
(43) Pub. Date: Dec. 21, 2023

(54) FAST AXIS WAVELENGTH BEAM COMBINING FOR BROAD AREA LASER DIODES

(71) Applicant: Lumentum Operations LLC, San Jose, CA (US)

(72) Inventors: John G. BAI, San Jose, CA (US); Victor ROSSIN, Mountain View, CA (US)

(21) Appl. No.: 18/329,448

(22) Filed: Jun. 5, 2023

Related U.S. Application Data
(60) Provisional application No. 63/366,513, filed on Jun. 16, 2022.

(51) Int. Cl. H01S 5/40; H01S 5/20; H01S 5/02253; H01S 5/024

(52) U.S. Cl. CPC H01S 5/4012; H01S 5/2036; H01S 5/4025; H01S 5/02253; H01S 5/02469

(57) ABSTRACT

An optical module includes a stepped structure that includes a plurality of steps, a plurality of laser diodes (e.g., broad area laser diodes (BALs)), a transform lens; a grating; and an output coupler (OC). At least one laser diode, of the plurality of laser diodes, is disposed on each step of the plurality of steps of the stepped structure. The transform lens is configured to receive a plurality of laser beams emitted by the plurality of laser diodes and to direct the plurality of laser beams to the grating. The grating is configured to receive and to combine the plurality of laser beams into a single laser beam, and to direct the single laser beam to the OC. The OC is configured to receive the single laser beam from the grating and to direct a portion of the of the single laser beam out of the optical module.

### CROSS-REFERENCE TO RELATED APPLICATION

This patent application claims priority to U.S. Patent Application No. 63/366,513, filed on Jun. 16, 2022, and entitled “OPTICAL MODULE WITH FAST-AXIS WAVELENGTH BEAM COMBINING USING BROAD AREA LASERS.” The disclosure of the prior application is considered part of and is incorporated by reference into this patent application.

### TECHNICAL FIELD

The present disclosure relates generally to an optical module and to fast axis wavelength beam combining for broad area laser diodes (BALs).

### BACKGROUND

A broad area laser diode (BAL) emits a laser beam with a fast axis divergence angle that is greater than a slow divergence angle of the laser beam.

### SUMMARY

In some implementations, an optical module comprising: a stepped structure that includes a plurality of steps; a plurality of laser diodes; a plurality of fast axis collimators (FACs); a transform lens; a grating; and an output coupler (OC), wherein: each step, of the plurality of steps of the stepped structure, is associated with a particular distance, in a lateral direction, from the transform lens that is different than respective distances of other steps of the plurality of steps, each laser diode, of the plurality of laser diodes, is disposed on a particular step, of the plurality of steps, that is different than the other steps of the stepped structure on which other laser diodes are disposed, each FAC, of the plurality of FACs, is disposed between a corresponding laser diode, of the plurality of laser diodes, and the transform lens, the plurality of laser diodes are configured to emit a plurality of laser beams to the plurality of FACs, the transform lens is configured to receive the plurality of laser beams from the plurality of FACs and to direct the plurality of laser beams to the grating, the grating is configured to receive the plurality of laser beams from the transform lens, to combine the plurality of laser beams into a single laser beam, and to direct the single laser beam to the OC, and the OC is configured to receive the single laser beam from the grating and to direct a portion of the of the single laser beam out of the optical module.

In some implementations, an optical module comprising: a stepped structure that includes a plurality of steps; a plurality of laser diodes; a transform lens; a grating; and an OC, wherein: at least one laser diode, of the plurality of laser diodes, is disposed on each step of the plurality of steps of the stepped structure, the transform lens is configured to receive a plurality of laser beams emitted by the plurality of laser diodes and to direct the plurality of laser beams to the grating, the grating is configured to receive the plurality of laser beams from the transform lens, to combine the plurality of laser beams into a single laser beam, and to direct the single laser beam to the OC, and the OC is configured to receive the single laser beam from the grating and to direct a portion of the of the single laser beam out of the optical module.

In some implementations, an optical module comprising: a stepped structure that includes a plurality of steps; a plurality of broad area laser diodes (BALs); a transform lens; and a grating; wherein: each step, of the plurality of steps of the stepped structure, is associated with a particular distance, in a lateral direction, from the transform lens that is different than respective distances of other steps of the plurality of steps, each BAL, of the plurality of BALs, is disposed on a particular step, of the plurality of steps, that is different than other steps of the stepped structure on which other laser diodes are disposed, the transform lens is configured to receive a plurality of laser beams emitted from the plurality of BALs and to direct the plurality of laser beams to the grating, and the grating is configured to receive the plurality of laser beams from the transform lens and to combine the plurality of laser beams into a single laser beam.

### BRIEF DESCRIPTION OF THE DRAWINGS

FIG. 1 is a diagram of an example implementation described herein.

FIGS. 2A-2B are diagrams of an example implementation described herein.

FIGS. 3A-3B are diagrams of an example implementation described herein.

FIG. 4 is a diagram of an example implementation described herein.

### DETAILED DESCRIPTION

The following detailed description of example implementations refers to the accompanying drawings. The same reference numbers in different drawings may identify the same or similar elements.

To provide a high-power laser beam (e.g., with kilowatt (kW)-class power), an optical module may utilize wavelength beam combining (WBC). Such an optical module can include a “laser bar” of multiple broad area laser diodes (BALs). Typically, the multiple BALs are arranged in a linear array within the laser bar, wherein each BAL is a same distance away from a transform lens (e.g., a Fourier transform lens). Each BAL may emit a laser beam that is collimated by a fast axis collimation lens (FAC) and/or a slow axis collimation lens (SAC) and then is directed to a grating by the transform lens. The grating combines the individual laser beams emitted by the BALs into a combined laser beam (e.g., that has power that is a combination of the individual laser beams) that is coupled into a fiber (e.g., of a fiber laser).

In some cases, n BALs (e.g., where n≥2) are stacked in the laser bar (e.g., stacked in a direction that is parallel to a fast axis of the laser beams emitted by the n BALs). For example, n BALs may stacked to roughly equalize two orthogonal beam parameter products (BPPs) for a round core of the fiber (e.g., into which the combined laser beam couples). Accordingly, by stacking the n BALs with a fill factor γ_{FA}, the n BALs may have a total fast axis BPP_{nFA} that is described using the following equation:

$${BPP}_{nFA} = \frac{n}{{γ}_{FA}} {BPP}_{FA} ,$$

where BPP_{FA} is the fast axis BPP of an individual BAL. Consequently, to ensure efficient fiber coupling, a maximum number of the n BALs is limited by the following relation:

$$\sqrt{{( {BPP}_{SA} )}^{2} + {( \frac{n}{{γ}_{FA}} {BPP}_{FA} )}^{2}} \leq {BPP}_{C} ,$$

where BPP_{SA} is the slow axis BPP of an individual BAL and BPP_{C} is the BPP of the fiber. Further, because the n BALs are arranged in a stack configuration, thermal management of the n BALs becomes difficult (e.g., because heat generated by operation of the n BALs is concentrated into an area associated with a footprint of the laser bar).

Some implementations described herein include an optical module that uses distributed laser diodes (e.g., BALs) spaced-apart at different horizontal and vertical distances from a transform lens (e.g., a fast axis transform lens (FATL) or another type of transform lens). Each laser diode is disposed on a step of a stepped structure and emits a laser beam with a particular wavelength (e.g., centered at the particular wavelength, such as after being wavelength locked, as described herein). Accordingly, the laser diodes emit laser beams that propagate toward the transform lens, wherein each laser beam is collimated by a corresponding FAC (e.g., that enables the laser diode that emitted the laser beam to be any distance from the transform lens) and then is directed by the transform lens to a grating. The grating converts respective angular and wavelength characteristics of the laser beams into a single laser beam that is directed to an output coupler (OC). The OC reflects a first portion of the single laser beam (e.g., that includes respective first portions of the laser beams) back through the optical module to wavelength-lock the BALs. Further, the OC passes a second portion (e.g., an unreflected remainder) of the single laser beam out of the optical module, such as to a fiber (e.g., to allow the single laser beam to couple into the fiber).

In some implementations, the stepped structure is configured to thermally conduct heat away from the laser diodes. That is, the stepped structure may be a heatsink (e.g., a passive heatsink), wherein each laser diode is disposed on a particular step of the stepped structure, which allows the laser diodes to be spaced-out in a distributed manner. Accordingly, heat that is generated by operating the laser diodes is dispersed across a large area of the stepped structure, which enables the stepped structure to effectively conduct the heat away from the laser diodes. Therefore, by removing heat from the laser diodes, the laser diodes may be higher powered (e.g., as compared to laser diodes stacked in a laser bar), and a brightness of the laser beams emitted by the laser diodes may therefore be increased. Accordingly, a brightness of the single laser beam (e.g., that is a combination of the laser beams) may also be increased. Further, using distributed laser diodes instead of a single laser bar increases reliability of the optical module.

In some implementations, the grating is positioned to be a particular distance from the transform lens, such as focal length of the transform lens. This allows the grating to convert respective angular and wavelength characteristics of the laser beams into combined wavelength characteristics of the single laser beam. For example, the grating is able to receive and overlap respective near field (NF) characteristics and/or respective far field (FF) characteristics of the laser beams to form the single laser beam. Accordingly, this causes the single laser beam to have an improved power, an improved numerical aperture (NA), and an improved BPP (e.g., in comparison to a combined beam formed when the grating is not a focal length away from the transform lens).

Accordingly, in some implementations, the optical module includes multiple columns of laser diodes to be disposed on the stepped structure. After collimation (e.g., in the fast axis) of the laser beams emitted by the laser diodes, the transform lens and grating are used to combine the laser beams in the fast axis. When a total number of laser diodes is n, a total BPP in the fast axis of the n laser diodes (BPP_{nFA}) is therefore improved from

$$\frac{n}{{γ}_{FA}}$$

BPP_{FA} to BPP_{FA} (where γ is the fill-factor of the single laser beam), while total BPP in a slow axis (BPP_{SA}) is the same as that of an individual diode laser. The optical module described herein therefore enhances module power and beam brightness, and thus dramatically improves dollar per watt ($/W) efficiency of the optical module. Furthermore, the locked and adjustable spectra enabled by the optical module is advantageous for pump or direct diode applications.

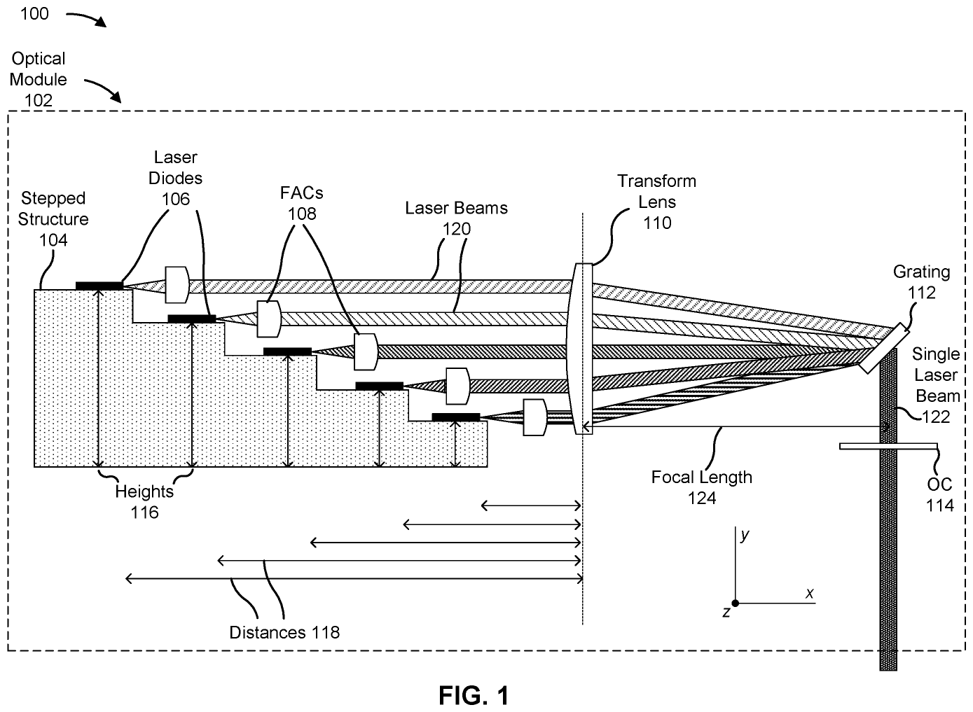

FIG. 1 is a diagram of an example implementation 100 described herein. As shown in FIG. 1, the example implementation 100 comprises an optical module 102, which may include a stepped structure 104, a plurality of laser diodes 106, a plurality of FACs 108, a transform lens 110, a grating 112, an output coupler (OC) 114, and/or one or more other components. FIG. 1 shows a side view of the optical module 102.

As shown in FIG. 1, the stepped structure 104 may include a plurality of steps. That is, the stepped structure may be a “staircase” structure. Each step may be associated with a height 116 (e.g., from a bottom of the stepped structure 104 or a bottom surface of the optical module 102, in a vertical direction that is parallel to the y axis shown in FIG. 1). For example, each step may be associated with a particular height 116 that is different than respective heights 116 of the other steps of the plurality of steps of the stepped structure 104. Additionally, each step may be associated with a distance (e.g., in a lateral direction, also referred to as a horizontal direction, that is parallel to the x axis shown in FIG. 1) from the transform lens 110 (e.g., from a focal axis of the transform lens 110, an input surface of the transform lens 110, an output surface of the transform lens 110, or another portion of the transform lens 110). For example, each step may be associated with a particular distance from the transform lens 110 that is different than respective distances (e.g., from the transform lens 110) of the other steps of the plurality of steps of the stepped structure 104.

In some implementations, the stepped structure 104 may be configured to thermally conduct heat (e.g., that is generated by one or more other components of the optical module 102) away from the optical module 102. That is, the stepped structure 104 may be a heatsink (e.g., a passive heatsink). For example, as shown in FIG. 1, the stepped structure 104 may be configured to thermally conduct heat in a vertical direction (e.g., in a downward direction that is parallel to the y axis shown in FIG. 1) from the optical module 102 to another component or system external the optical module 102 (not pictured in FIG. 1), such as to another heatsink or to another thermally conductive element that is below the stepped structure 104. In this way, the stepped structure 104 may be configured to facilitate dissipation of heat generated by the optical module 102 and thereby enable temperature regulation of the optical module 102.

The plurality of laser diodes 106 may be configured to emit a plurality of laser beams 120. That is, each laser diode 106, of the plurality of laser diodes 106, may be configured to emit a laser beam 120 (e.g., in a lateral direction, or horizontal direction, that is parallel to the x axis shown in FIG. 1). For example, each laser diode 106 may emit a laser beam 120 that is associated with a particular wavelength (e.g., centered at the particular wavelength, such as after being wavelength locked, as described herein) that is different than respective wavelengths of laser beams 120 emitted by other laser diodes 106 of the plurality of laser diodes 106. This is shown in FIG. 1, where each laser beam 120 is depicted as having a distinct patterning. In some implementations, each laser diode 106, of the plurality of laser diodes 106, may be configured to be wavelength-locked at a particular wavelength (e.g., within 1 nanometer (nm)) at which the laser diode 106 is configured to emit a laser beam 120 (e.g., due to a portion of the laser beam 120 that is reflected back to the laser diode 106, such as by the OC 114, as further described herein). Accordingly, because the plurality of laser diodes 106 may be configured to the be wavelength-locked, in some implementations, the plurality of laser diodes 106 may be configured to emit laser beams within a same wavelength range (e.g., with a width that is less than or equal to 10 nm, 15 nm, 20 nm, 25 nm, 30 nm, or 35 nm), where each laser diode 106 is configured to be wavelength-locked at a particular wavelength (e.g., within 1 nm) within the wavelength range.

In some implementations, each laser diode 106 may be a BAL. For example, each laser diode 106 may be configured to emit a laser beam 120 that is emitted with a fast axis divergence angle that is greater than a slow divergence angle of the laser beam 120. With reference to FIG. 1, the fast axis may be parallel to the y axis, and the slow axis may be parallel to the z axis.

Each laser diode 106 may be disposed on a step of the stepped structure 104. For example, as shown in FIG. 1, each laser diode 106 may be disposed on a particular step of the stepped structure 104 that is different than other steps of the stepped structure 104 on which other laser diodes 106 are disposed. Accordingly, each laser diode 106 may be associated with a particular height 116 (e.g., from the bottom surface of the stepped structure 104) and a particular distance 118 (e.g., from the transform lens 110) of the particular step on which the laser diode 106 is disposed. In some implementations, each laser diode 106 may be disposed on a corresponding submount (not shown in FIG. 1) that is disposed on the particular step of the stepped structure 104.

In some implementations, the stepped structure 104 may be configured to thermally conduct heat that is generated by the plurality of laser diodes 106 (e.g., due to operation of the plurality of laser diodes 106) disposed on the plurality of steps of the stepped structure 104 away from the optical module 102. Further, because each laser diode 106 may be disposed on a corresponding step of the stepped structure 104, the plurality of laser diodes 106 may be physically spaced apart (e.g., in the lateral direction, or horizontal direction, that is parallel to the x axis shown in FIG. 1) across the stepped structure 104, which allows portions of the stepped structure 104 (e.g., that are associated with the steps of the stepped structure 104) to respectively thermally conduct heat generated by the plurality of laser diodes 106. Accordingly, the stepped structure 104 is able to provide an improved thermal conductivity performance as compared to a heat sink that could be used for a vertical stack configuration of the plurality of laser diodes 106. Therefore, the plurality of laser diodes 106 may be higher powered (e.g., as compared to laser diodes 106 that are vertically stacked on top of each other), and a brightness of the plurality of laser beams 120 may therefore be increased.

Each laser beam 120 may propagate via an optical path from the laser diode 106 that emitted the laser beam 120 to the grating 112 (e.g., to an input surface of the grating 112) via the transform lens 110. For example, each laser beam 120 may transmit via a particular optical path to the grating 112 that is different than optical paths propagated by other laser beams 120 of the plurality of other laser beams 120. This may be due to the plurality of laser diodes 106 being associated with different respective heights 116 and distances 118. Accordingly, a length of the optical path of each laser beam 120 to the grating 112 may be different than optical path lengths of other laser beams 120 of the plurality of laser beams 120.

The plurality of FACs 108 may correspond to the plurality of laser diodes 106. For example, each FAC 108 may be associated with a particular laser diode 106. As shown in FIG. 1, a FAC 108 may be disposed along an optical path of a laser beam 120 emitted from a corresponding laser diode 106, of the plurality of laser diodes 106, between the corresponding laser diode 106 and the transform lens 110. In some implementations, a FAC 108 that corresponds to a laser diode 106 may be disposed on the submount (not shown in FIG. 1) of the laser diode 106 to ensure that the FAC 108 is positioned and/or aligned between the laser diode 106 and the transform lens 110. Accordingly, each FAC 108 may be associated with the height 116 of the laser diode 106 to which the FAC 108 corresponds (e.g., to the height 116 of the step of the stepped structure 104 on which the laser diode 106 is disposed).

Each FAC 108 may be configured to receive a laser beam 120 (e.g., emitted from a corresponding laser diode 106 of the plurality of laser diodes 106) and to collimate the laser beam 120. For example, the FAC 108 may collimate the laser beam 120 in the fast axis (e.g., that is parallel to the y axis shown in FIG. 1). The FAC 108 may be further configured to direct the laser beam 120 to the transform lens 110. In some implementations, the FAC 108 may be configured to direct the laser beam 120 to the transform lens 110 via one or more other components of the optical module 102, such as via one or more optical elements (e.g., one or more lenses, one or more reflectors, and/or one or more or other optical elements).

The transform lens 110 may be configured to receive the plurality of laser beams 120, such as from the plurality of FACs 108. Further, the transform lens 110 may be configured to direct the plurality of laser beams 120 to the grating 112. For example, the transform lens 110 may be a converging lens (e.g., a Fourier transform lens, an FATL, and/or another type of converging lens) that is configured to converge the plurality of laser beams 120 on the grating 112 (e.g., converge the plurality of laser beams 120 in the fast axis, which is parallel to the y axis shown in FIG. 1). In some implementations, the transform lens 110 may be configured to direct the plurality of laser beams 120 to the grating 112 via one or more other components of the optical module 102, such as via one or more optical elements (e.g., one or more lenses, one or more reflectors, and/or one or more or other optical elements).

The grating 112 may be configured to receive the plurality of laser beams 120, such as from the transform lens 110. The grating 112 may be a diffractive grating, a transmission grating, a diffractive transmission grating, or another type of grating, and therefore may be configured to combine (e.g., using WBC) the plurality of laser beams 120 into a single laser beam 122. The single laser beam 122 may have high power (e.g., a combination of respective powers of the plurality of laser beams 120) and, therefore, high brightness. Further, the grating 112 may be configured to direct the single laser beam 122 to the OC 114. In some implementations, the grating 112 may be configured to direct the single laser beam 122 to the OC 114 via one or more other components of the optical module 102, such as via one or more optical elements (e.g., one or more lenses, one or more reflectors, and/or one or more or other optical elements).

In some implementations, the grating 112 may be positioned at a particular distance from the transform lens 110. As shown in FIG. 1, the particular distance may be equal to a focal length 124 of the transform lens 110 (e.g., within a tolerance, which may be less than or equal to 1%, 2%, 3%, 5%, or 10% of the focal length 124). This may allow the grating 112 to convert respective angular and wavelength characteristics of the plurality of laser beams 120 into combined wavelength characteristics of the single laser beam 122. For example, by positioning the grating 112 at the particular distance from the transform lens 110, the grating 112 is able to receive and overlap respective NF characteristics and/or respective FF characteristics of the plurality of laser beams 120 to form the single laser beam 122. Accordingly, this allows the single laser beam 122 to have an improved power, an improved NA, and an improved BPP.

The OC 114 may be configured to receive the single laser beam 122, such as from the grating 112. Further, the OC 114 may be configured to reflect a first portion of the single laser beam 122 back to the plurality of laser diodes 106 (e.g., in a reverse propagation direction via the grating 112, the transform lens 110, and the plurality of FACs 108). The first portion of the single laser beam 122 may include less than or equal to a particular percentage of the single laser beam 122, wherein the particular percentage is, for example, less than or equal to 1%, 5%, and/or 10%. In this way, respective portions of the plurality of laser beams 120 emitted by the plurality of laser diodes 106 (e.g., that are part of the first portion of the single laser beam 122) may be reflected back to the plurality of laser diodes 106 to cause the plurality of laser diodes 106 to be wavelength-locked.

For example, a particular laser diode 106 may emit a particular laser beam 120 associated with a particular wavelength, which may propagate to the OC 114 as part of the single laser beam 122 (in a similar manner as described elsewhere herein). The OC 114 may reflect a portion of the single laser beam 122, which includes a portion of the particular laser beam 120. This causes the portion of the particular laser beam 120 to propagate to the particular laser diode 106 and thereby causes the particular laser diode 106 to be wavelength-locked at the particular wavelength. Accordingly, each laser diode 106, of the plurality of laser diodes 106, may be wavelength-locked at a particular wavelength due to the height 116 of the laser diode 106, a length of an optical path of a laser beam 120 emitted by the laser diode 106 (e.g., from the laser diode 106 to the grating 112), an angle at which the laser beam 120 impinges on the grating 112 (e.g., after propagating from the laser diode 106 to the 112 via a corresponding FAC 108 and the transform lens 110), and/or a distance of the grating 112 from the transform lens 110.

Accordingly, in some implementations, each laser diode 106, of the plurality of laser diodes 106, may be wavelength-locked at a particular wavelength (e.g., within 1 nm of the particular wavelength) that is different than respective wavelengths at which other laser diodes 106 are wavelength-locked. In some implementations, the plurality of laser diodes 106 may be wavelength-locked within a wavelength-locked range (e.g., each laser diode 106 may be wavelength-locked at a particular wavelength that is greater than or equal to a minimum of the wavelength-locked range and that is less than or equal to a maximum of the wavelength-locked range). A width of the wavelength-locked range (e.g., a difference between the maximum and the minimum of the wavelength-locked range) may be less than or equal to a width threshold. The width threshold may less than or equal to, for example, 2 nm, 4 nm, 6 nm, 8 nm, or 10 nm.

Additionally, or alternatively, as shown in FIG. 1, the OC 114 may be configured to direct a second portion of the single laser beam 122 (e.g., as a combined laser beam) out of the optical module 102. For example, the OC 114 may be configured to direct a remainder of the single laser beam 122 (e.g., that is not reflected by the OC 114) out of the optical module 102. In some implementations, the OC 114 may be configured to direct the single laser beam 122 out of the optical module via one or more other components of the optical module 102, such as via one or more optical elements (e.g., one or more lenses, one or more reflectors, and/or one or more or other optical elements). In some implementations, the OC 114 may cause the single laser beam 122 to be emitted from the optical module 102 to a fiber (e.g., an output fiber of a fiber laser).

FIG. 1 is provided as an example. Other examples may differ from what is described with regard to FIG. 1.

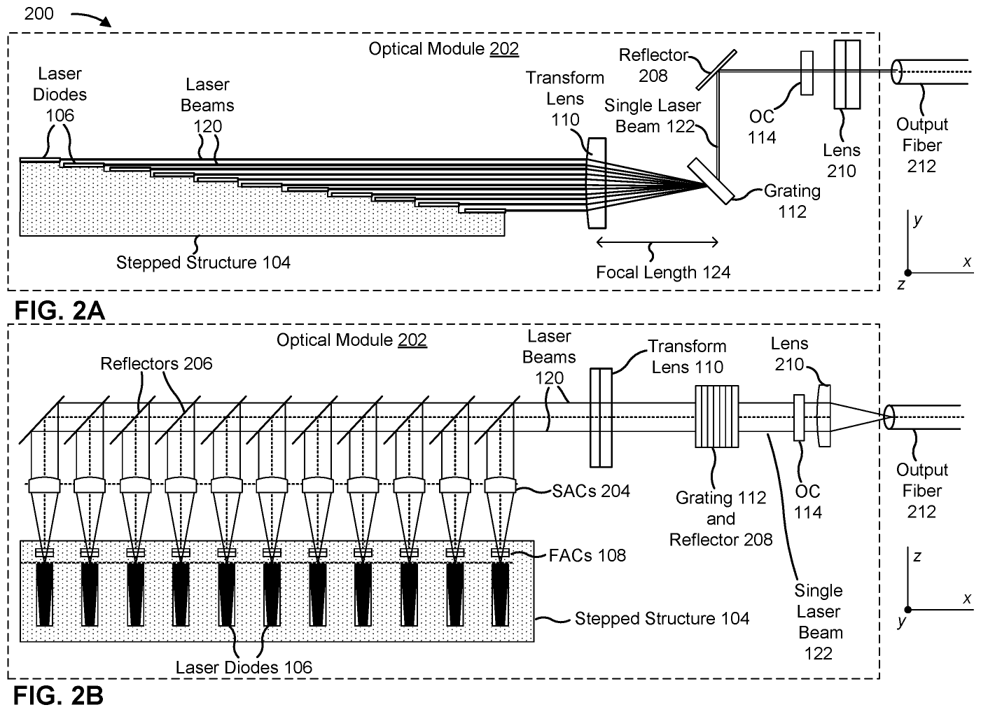

FIGS. 2A-2B are diagrams of an example implementation 200 described herein. As shown in FIGS. 2A-2B, the example implementation 200 comprises an optical module 202. The optical module 202 may be similar to the optical module 102, and may therefore include the stepped structure 104, the plurality of laser diodes 106, the plurality of FACs 108, the transform lens 110, the grating 112, and/or the OC 114 (e.g., configured in a similar manner as that described herein in relation to FIG. 1). As further shown in FIGS. 2A-2B, the optical module 202 may also include one or more other components, such as a plurality of SACs 204, a plurality of reflectors 206, a reflector 208, and a lens 210. FIG. 2A shows a side view of the of the optical module 202, and FIG. 2B shows a top-down view of the optical module 202.

In a similar manner as described herein in relation to FIG. 1, the plurality of laser diodes 106 (e.g., that are disposed on respective steps of the stepped structure 104), may emit the plurality of laser beams 120. The plurality of laser beams 120 then may propagate to the transform lens 110 via the plurality of FACs 108, and via at least one of the plurality of SACs 204 or the plurality of reflectors 206, as described herein.

As shown in FIG. 2B, the plurality of SACs 204 may correspond to the plurality of laser diodes 106. For example, each SAC 204 may be associated with a particular laser diode 106. As shown in FIG. 2B, a SAC 204 may be disposed along an optical path of a laser beam 120 emitted from a corresponding laser diode 106, of the plurality of laser diodes 106, between the corresponding laser diode 106 (and a FAC 108 associated with the laser diode 106) and the transform lens 110 (and, optionally, a corresponding reflector 206, further described herein). In some implementations, a SAC 204 that corresponds to a laser diode 106 may be disposed on a submount (not shown in FIGS. 2A-2B) of the laser diode 106 to ensure that the SAC 204 is positioned and/or aligned between the laser diode 106 and the transform lens 110. Accordingly, each SAC 204 may be associated with a height 116 of the laser diode 106 (described herein in relation to FIG. 1) to which the SAC 204 corresponds (e.g., to the height 116 of the step of the stepped structure 104 on which the laser diode 106 is disposed).

Each SAC 204 may be configured to receive a laser beam 120 (e.g., emitted from a corresponding laser diode 106 of the plurality of laser diodes 106) and to collimate the laser beam 120 (e.g., after a corresponding FAC 108 collimates the laser beam 120). For example, the SAC 204 may collimate the laser beam 120 in a slow axis (e.g., that is parallel to the z axis shown in FIGS. 2A-2B), such as after a corresponding FAC 108 collimates the laser beam 120 in the fast axis (e.g., that is parallel to the y axis shown in FIGS. 2A-2B). The SAC 204 may be further configured to direct the laser beam 120 to the transform lens 110. In some implementations, the SAC 204 may be configured to direct the laser beam 120 to the transform lens 110 via one or more other components of the optical module 102, such as via one or more optical elements (e.g., one or more lenses, one or more reflectors, and/or one or more or other optical elements). For example, as shown in FIG. 2B, the SAC 204 may be configured to direct the laser beam 120 to the transform lens 110 via a corresponding reflector 206.

As shown in FIG. 2B, the plurality of reflectors 206 may correspond to the plurality of laser diodes 106. For example, each reflector 206 may be associated with a particular laser diode 106. As shown in FIG. 2B, a reflector 206 may be disposed along an optical path of a laser beam 120 emitted from a corresponding laser diode 106, of the plurality of laser diodes 106, between the corresponding laser diode 106 (and a FAC 108 and a SAC 204 associated with the laser diode 106) and the transform lens 110. In some implementations, a reflector 206 that corresponds to a laser diode 106 may be disposed on the submount (not shown in FIGS. 2A-2B) of the laser diode 106 to ensure that the reflector 206 is positioned and/or aligned between the laser diode 106 and the transform lens 110. Accordingly, each reflector 206 may be associated with the height 116 of the laser diode 106 (described herein in relation to FIG. 1) to which the reflector 206 corresponds (e.g., to the height 116 of the step of the stepped structure 104 on which the laser diode 106 is disposed).

Each reflector 206 may be configured to receive a laser beam 120 (e.g., emitted from a corresponding laser diode 106 of the plurality of laser diodes 106) and to direct the laser beam 120 to the transform lens 110. For example, the reflector 206 may be a mirror (e.g., a turning mirror) that is configured to change a propagation direction of the laser beam 120 such that the laser beam 120 is directed to the transform lens 110. Including the plurality of reflectors 206 is optional, where their inclusion enables folded optical paths of the plurality of laser beams 120 for a more compact optical module 202.

In a similar manner as that described herein in relation to FIG. 1, the transform lens 110 may be configured to receive, transform, and direct the plurality of laser beams 120 to the grating 112, which may be configured to combine the plurality of laser beams 120 into the single laser beam 122. The grating 112 may be configured to direct the single laser beam 122 to the OC 114, such as via the reflector 208.

As shown in FIG. 2A, the reflector 208 may be disposed along an optical path of the single laser beam 122 (e.g., that is formed by the grating 112) between the grating 112 and the OC 114. The reflector 208 may be configured to receive the single laser beam 122 and to direct the single laser beam 122 to the OC 114. For example, the reflector 208 may be a mirror (e.g., a turning mirror) that is configured to change a propagation direction of the single laser beam 122 such that the single laser beam 122 is directed to the OC 114. The reflector 208 is optional, where its inclusion enables a folded optical path of the single laser beam 122 for a more compact optical module 202.

The OC 114 may be configured in a similar manner as that described herein in relation to FIG. 1. For example, the OC 114 may be configured to receive the single laser beam 122 and reflect a first portion of the single laser beam 122 back to the plurality of laser diodes 106 (e.g., to wavelength-lock the plurality of laser diodes 106), and to direct a second portion of the single laser beam 122 out of the optical module 202, such as to an output fiber 212 (e.g., that is an output fiber of a fiber laser).

As shown in FIGS. 2A-2B, in some implementations, the lens 210 may be disposed along an optical path of the second portion of the single laser beam 122 (e.g., that is provided by the OC 114) between the OC 114 and the output fiber 212. The lens 210 may be configured to receive the second portion of the single laser beam 122 and to direct the second portion of the single laser beam 122 to the output fiber 212. For example, the lens 210 may be a coupling lens (e.g., a cylindrical slow axis coupling (CSAC) lens) that is configured to converge the second portion of the single laser beam 122 on the output fiber 212 (e.g., converge the second portion of the single laser beam 122 in the slow axis, which is parallel to the z axis shown in FIGS. 2A-2B). In some implementations, the lens 210 may be configured to direct the second portion of the single laser beam 122 to the output fiber 212 via one or more other components of the optical module 202, such as via one or more optical elements (e.g., one or more lenses, one or more reflectors, and/or one or more or other optical elements).

FIGS. 2A-2B are provided as an example. Other examples may differ from what is described with regard to FIGS. 2A-2B.

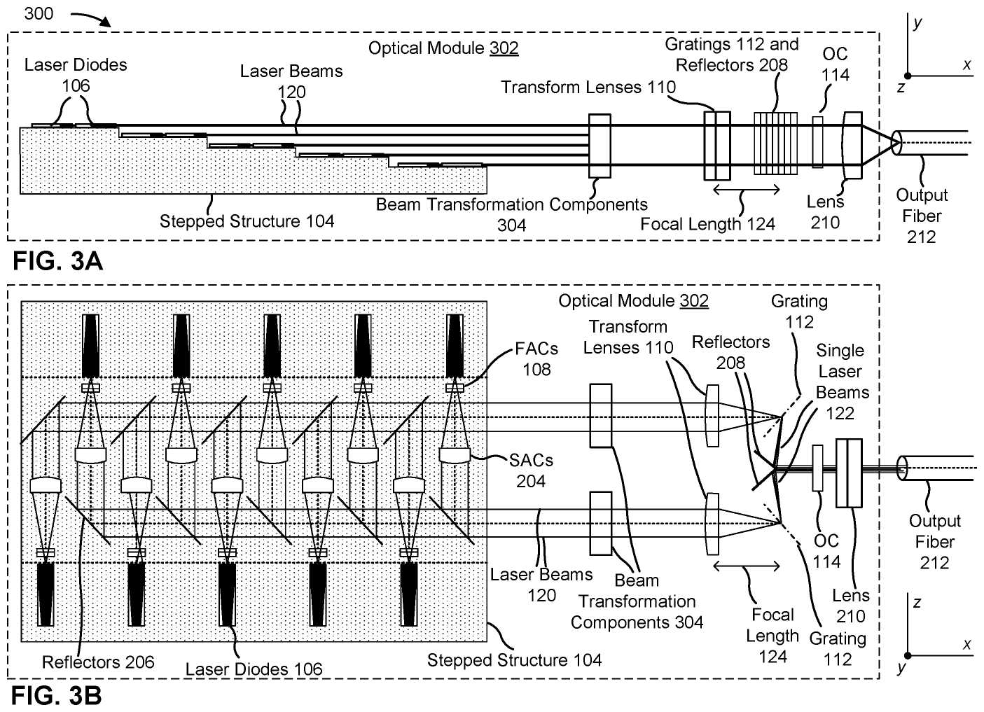

FIGS. 3A-3B are diagrams of an example implementation 300 described herein. As shown in FIGS. 3A-3B, the example implementation 300 comprises an optical module 302. The optical module 302 may be similar to the optical module 102 and/or the optical module 202, and may therefore include the stepped structure 104, the plurality of laser diodes 106, the plurality of FACs 108, the OC 114, the plurality of SACs 204, the plurality of reflectors 206, and/or the lens 210 (e.g., configured in a similar manner as that described herein in relation to FIGS. 1 and 2A-2B). Notably, the optical module 302 may include a plurality of transform lenses 110, a plurality of gratings 112, and/or a plurality of reflectors 208, rather than only one of each of these components (e.g., as described herein in relation to FIGS. 1 and 2A-2B). Additionally, the optical module 302 may also include one or more other components, such as a plurality of beam transformation components 304. FIG. 3A shows a side view of the of the optical module 302, and FIG. 3B shows a top-down view of the optical module 302.

As shown in FIG. 3B, the plurality of laser diodes 106 may be configured as two columns (e.g., that extend in the lateral direction, or horizontal direction, that is parallel to the x axis shown in FIGS. 3A-3B). Accordingly, two laser diodes 106 (one from each column), of the plurality of laser diodes 106, may be disposed on a same step of the stepped structure 104. For example, as shown in FIGS. 3A-3B, a laser diode 106 from a first column (the top column shown in FIG. 3B) may be disposed on a same step (as shown in FIG. 3A) of the stepped structure 104 as a laser diode 106 from a second column (the bottom column shown in FIG. 3B). Accordingly, each pair of laser diodes 106 may be associated with a particular height 116 (e.g., from the bottom surface of the stepped structure 104) of the particular step on which the laser diode 106 is disposed. In some implementations, each pair of laser diodes 106 may be disposed on a corresponding submount (not shown in FIGS. 3A-3B) that is disposed on the particular step of the stepped structure 104.

As further shown in FIG. 3B, each laser diode 106 may be positioned to emit a laser beam 120 toward a central portion of the stepped structure 104. For example, a first laser diode 106 from the first column may be configured to emit a first laser beam 120 in a first direction (e.g., a downward direction, that is parallel to the z axis shown in FIG. 3B) toward the central portion of the stepped structure 104, and a second laser diode 106 from the second column may be configured to emit a second laser beam 120 in a second direction (e.g., an upward direction, that is parallel to the z axis shown in FIG. 3B) toward the central portion of the stepped structure 104.

In some implementations, each column of the plurality of laser diodes 106 may be wavelength-locked within a same wavelength-locked range (e.g., each laser diode 106 of each column may be wavelength-locked at a particular wavelength that is greater than or equal to a minimum of the wavelength-locked range and that is less than or equal to a maximum of the wavelength-locked range). A width of the wavelength-locked range (e.g., a difference between the maximum and the minimum of the wavelength-locked range) may be less than or equal to a width threshold. The width threshold may less than or equal to, for example, 2 nm, 4 nm, 6 nm, 8 nm, or 10 nm. Alternatively, the columns of the plurality of laser diodes 106 may be wavelength-locked within different, or only partially overlapping, wavelength-locked ranges.

Each laser diode 106 may be associated with a FAC 108, a SAC 204, and/or a reflector 206 (e.g., is a similar manner as that described herein in relation to FIGS. 1 and 2A-2B). Accordingly, a FAC 108, a SAC 204, and/or a reflector 206 may be disposed along an optical path of a laser beam 120 emitted by a corresponding laser diode 106. Further, first reflectors 206, of the plurality of reflectors 206, that are associated with the first column of laser diodes 106 may be configured to receive first laser beams 120 (e.g., emitted by the first column of laser diodes 106) and to direct the first laser beams 120 to a first beam transformation component 304 (shown as the bottom beam transformation component 304 in FIG. 3B) of the plurality of beam transformation components 304. Second reflectors 206, of the plurality of reflectors 206, that are associated with the second column of laser diodes 106 may be configured to receive second laser beams 120 (e.g., emitted by the second column of laser diodes 106) and to direct the second laser beams 120 to a second beam transformation component 304 (shown as the top beam transformation component 304 in FIG. 3B) of the plurality of beam transformation components 304.

Each beam transformation component 304 may include a beam transformation system (BTS), a Dove prism, a pair of mirrors, or another beam transformation component, and may be configured to receive a laser beam 120; modify one or more characteristics of the laser beam 120, such as a shape or profile of the laser beam 120, and/or or rotate the laser beam 120 (e.g., by a particular amount of degrees, such as 90 degrees); and to direct the laser beam 120 to a corresponding transform lens 110. For example, when a fast axis of the laser beam 120 is parallel to the y axis shown in FIGS. 3A-3B when received by the beam transformation component 304, the beam transformation component 304 may modify the laser beam 120 to cause the fast axis of the laser beam 120 to be parallel to the x axis shown in FIGS. 3A-3B. This may enable, for example, other components of the optical module 302 to be mounted on a same surface (e.g., a bottom, interior surface) of the optical module 302, which may not be possible when the beam transformation component 304 is not otherwise present. Further, the first beam transformation component 304 may direct the first laser beams 120 to a first transform lens 110 (shown as the bottom transform lens 110 in FIG. 3B), of the plurality of transform lenses 110, and the second beam transformation component 304 may direct the second laser beams 120 to a second transform lens 110 (shown as the bottom transform lens 110 in FIG. 3B) of the plurality of transform lenses 110.

Each transform lens 110 may be configured in a similar manner as elsewhere described herein. Accordingly, the first transform lens 110 may be configured to receive, transform, and direct the first plurality of laser beams 120 to a first grating 112 (shown as the bottom grating 112 in FIG. 3B), of the plurality of gratings 112, and the second transform lens 110 may be configured to receive, transform, and direct the second plurality of laser beams 120 to a second grating 112 (shown as the top grating 112 in FIG. 3B) of the plurality of gratings 112.

Each grating 112 may be configured in a similar manner as elsewhere described herein. Accordingly, the first grating 112 may be configured to combine the first plurality of laser beams 120 into a first single laser beam 122, and the second grating 112 may be configured to combine the second plurality of laser beams 120 into a second single laser beam 122. Each grating 112 may be configured to direct a respective single laser beam 122 to the OC 114, such as via a corresponding reflector 208 of the plurality of reflectors 208.

In this way, the plurality of transform lenses 110 and the plurality of gratings 212 may be configured to provide WBC of the first plurality of laser beams 120 into the first single laser beam 122, and of the second plurality of laser beams 120 into a second single laser beam 122. For example, the first transform lens 110 and the first grating 212 may provide WBC of the first plurality of laser beams 120 into the first single laser beam 122, and the second transform lens 110 and the second grating 212 may provide WBC of the second plurality of laser beams 120 into the second single laser beam 122.

Each reflector 208 may be configured in a similar manner as elsewhere described herein. Accordingly, a reflector 208 may be disposed along an optical path of a single laser beam 122 (e.g., that is formed by a corresponding grating 112) between the corresponding grating 112 and the OC 114. The reflector 208 may be configured to receive the single laser beam 122 and to direct the single laser beam 122 to the OC 114. For example, the reflector 208 may be a mirror (e.g., a turning mirror) that is configured to change a propagation direction of the single laser beam 122 such that the single laser beam 122 is directed to the OC 114. Accordingly, the first reflector 208 may be configured to receive and direct the first single laser beam 122 to the OC 114, and the second reflector 208 may be configured to receive and direct the second single laser beam 122 to the OC 114.

In this way, the plurality of reflectors 208 may be configured to spatially combine the first single laser beam 122 and the second single laser beam 122 (e.g., in a non-overlapped stack, or a non-overlapped column) when directing the first single laser beam 122 and the second single laser beam 122 to the OC 114. For example, the plurality of reflectors 208 may direct the first single laser beam 122 and the second single laser beam 122 to the OC 114 such that the first single laser beam 122 and the second single laser beam 122 impinge on the OC 114 in a stack, or column, where the first single laser beam 122 and the second single laser beam 122 are separated by a gap, as described herein. In this way, the plurality of reflectors 208 (e.g., the first reflector 208 and the second reflector 208) may be configured to provide spatial beam combination (SBC) of the first single laser beam 122 and the second single laser beam 122 (e.g., after the first grating 112 provides WBC of the first plurality of laser beams 120 into the first single laser beam 122, and after the second grating 112 provides WBC of the second plurality of laser beams 120 into the second single laser beam 122).

The OC 114 may be configured in a similar manner as elsewhere described herein. Accordingly, the OC 114 may be configured to receive respective single laser beams 122 from the plurality of gratings 112. The OC 114 may be configured to receive the first single laser beam 122 and the second single laser beam 122 as spatially combined single laser beams (e.g., as a non-overlapped stack, or a non-overlapped column). For example, the OC 114 may include a first portion that is configured to receive the first single laser beam 122 and a second portion that is configured to receive the second single laser beam 122. The first portion and the second portion may each be covered with a coating, such as a partially reflective (PR) coating (e.g., to reflect a first portion of light and to pass a second portion of light, as described herein). The first portion and the second portion may be separated by a gap. A size of the gap (e.g., a distance between an edge of the first single laser beam 122 and an edge of the single laser beam) may be less than or equal to a size threshold. The size threshold may be greater than or equal to 50 μm, 100 μm, 150 μm, 200 μm, 250 μm, 300 μm, 350 μm, 375 μm, 395 μm, 400 μm, 410 μm, or 420 μm. Accordingly, the OC 114 may have a greater width than a width of the OC 114 described herein in relation to FIGS. 1A-1B and 2A-2B (e.g., have a width that is at least twice as large).

The gap may be configured to prevent the first portion of the OC 114 from receiving any portion of the second single laser beam 122, and to prevent the second portion of the OC 114 from receiving any portion of the first single laser beam 122. This may cause the OC 114 to be configured to not reflect some of the first single laser beam 122 back to the second column of laser diodes 106 and some of the second single laser beam 122 back to the first column of laser diodes 106, as further described herein. Further, the gap may covered with a coating, such as an anti-reflective (AR) coating, to minimize an amount of reflection of any of the first single laser beam 122 or the second single laser beam 122 that impinges on the gap.

Further, the OC 114 may be configured to reflect respective first portions of the single laser beams 122 back to the plurality of laser diodes 106 (e.g., in a reverse propagation direction via the plurality of reflectors 208, the plurality of gratings 112, the plurality of transform lenses 110, the plurality of beam transformation components 304, the plurality of reflectors 206, the plurality of SACs 204, and/or the plurality of FACs 108). In this way, each laser diode 106 may be wavelength-locked, in a similar manner as that described elsewhere herein.

In some implementations, the first portion of the OC 114 (e.g., that received the first single laser beam 122) may reflect respective first portions of the first laser beams 120 that are included in the first single laser beam 122 back to the first column of laser diodes 106 to wavelength-lock the first column of laser diodes 106. The second portion of the OC 114 (e.g., that received the second single laser beam 122) may reflect respective second portions of the second laser beams 120 that are included in the second single laser beam 122 back to the second column of laser diodes 106 to wavelength-lock the second column of laser diodes 106.

Additionally, or alternatively, as shown in FIGS. 3A-3B, the OC 114 may be configured to direct respective second portions of the single laser beams 122 out of the optical module 202, such as to the output fiber 212. For example, the first portion of the OC 114 (e.g., that received the first single laser beam 122) may direct a second portion of the first single laser beam 122 out of the optical module 202, and the second portion of the OC 114 (e.g., that received the first single laser beam 122) may direct a second portion of the second single laser beam 122 out of the optical module 202.

The lens 210 may be configured in a similar manner as elsewhere described herein. Accordingly, as shown in FIGS. 3A-3B, the lens 210 may be disposed along an optical path of the respective second portions of the single laser beams 122 (e.g., that is provided by the OC 114) between the OC 114 and the output fiber 212. The lens 210 may be configured to receive the respective second portions of the single laser beams 122 and to direct the respective second portions of the single laser beams 122 to the output fiber 212. For example, the lens 210 may be configured to receive the second portion of the first single laser beam 122 from the first portion of the OC 114, and to receive the second portion of the second single laser beam 122 from the second portion of the OC 114. Accordingly, the lens 210 may be configured to direct the second portion of the first single laser beam 122 and the second portion of the second single laser beam 122 to the output fiber 212. In some implementations, because the lens 210 is configured receive and direct multiple single laser beams 122, the lens 210 may have a different width and/or a different focal length than a width and/or focal length of the lens 210 described herein in relation to FIGS. 2A-2B.

FIGS. 3A-3B are provided as an example. Other examples may differ from what is described with regard to FIGS. 3A-3B.

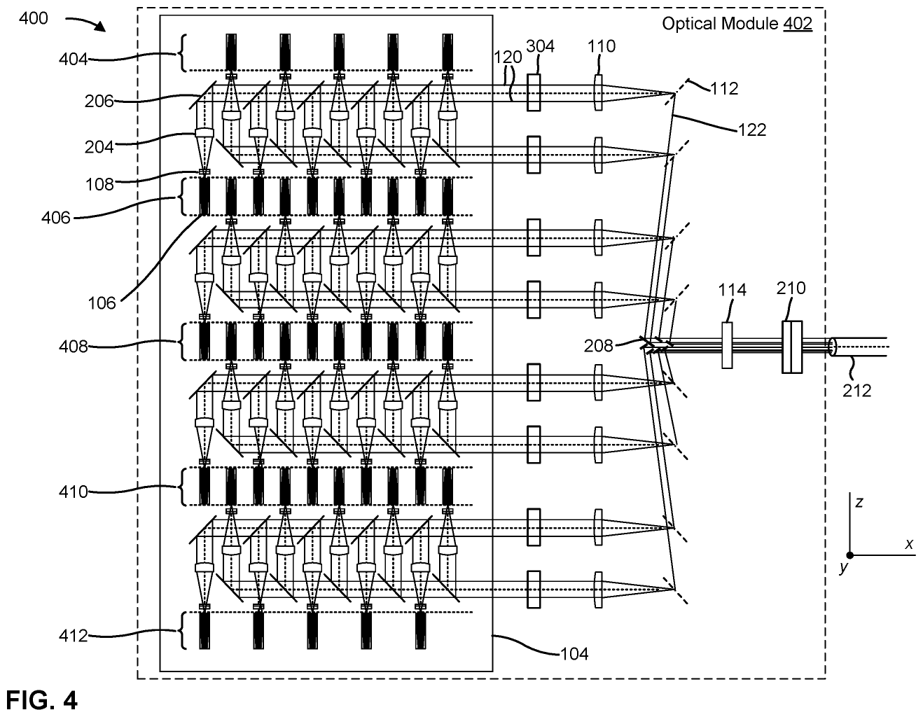

FIG. 4 is a diagram of an example implementation 400 described herein. As shown in FIG. 4, the example implementation 400 comprises an optical module 302. The optical module 402 may be similar to the optical module 102, the optical module 202, and/or the optical module 302, and may therefore include the stepped structure 104, the plurality of laser diodes 106, the plurality of FACs 108, the plurality of transform lenses 110, the plurality of gratings 112, the OC 114, the plurality of SACs 204, the plurality of reflectors 206, plurality of reflectors 208, and/or the lens 210 (e.g., configured in a similar manner as that described herein in relation to FIGS. 1, 2A-2B, and 3A-3B). The optical module 402 may also include one or more other components. FIG. 4 shows a top-down view of the optical module 402.

The plurality of laser diodes 106 may be configured as multiple columns of laser diodes. For example, as shown in FIG. 4, the plurality of laser diodes 106 may be configured as five columns (e.g., shown as columns 404, 406, 408, 410, and 412, that extend in the lateral direction, or horizontal direction, that is parallel to the x axis shown in FIG. 4). Accordingly, respective laser diodes 106 from two or more of the multiple columns may be disposed on a same step of the stepped structure 104. For example, a first set of laser diodes 106 that comprises respective laser diodes 106 (e.g., left-most laser diodes 106 as shown in FIG. 4) from the column 406, the column 408, the column 410, and the column 412, may be disposed on a first step of the stepped structure 104. As another example, a second set of laser diodes 106 that comprises respective laser diodes 106 (e.g., right-most laser diodes 106 as shown in FIG. 4) from the column 404, the column 406, the column 408, and the column 410, and the column 412, may be disposed on a second step of the stepped structure 104. Accordingly, the first set of laser diodes 106 may be associated with a first height 116 of the first step, and the second set of laser diodes 106 may be associated with a second height 116 of the second step.

As further shown in FIG. 4, each laser diode 106 of a column may be positioned to emit a laser beam 120 toward an internal portion of the stepped structure 104. For example, each laser diode 106 of the column 404 may be configured to emit a laser beam 120 in a first direction (e.g., a downward direction, that is parallel to the z axis shown in FIG. 4). As another example, each laser diode 106 of a first portion of laser diodes 106 of the column 406 may be configured to emit a laser beam 120 in the first direction, and each laser diode 106 of a second portion of laser diodes 106 of the column 406 may be configured to emit a laser beam 120 in a second direction (e.g., an upward direction, that is parallel to the z axis shown in FIG. 4).

In some implementations, each column of the plurality of laser diodes 106 may be wavelength-locked within a same wavelength-locked range (e.g., each laser diode 106 of each column may be wavelength-locked at a particular wavelength that is greater than or equal to a minimum of the wavelength-locked range and that is less than or equal to a maximum of the wavelength-locked range). A width of the wavelength-locked range (e.g., a difference between the maximum and the minimum of the wavelength-locked range) may be less than or equal to a width threshold. The width threshold may less than or equal to, for example, 2 nm, 4 nm, 6 nm, 8 nm, or 10 nm. Alternatively, the columns of the plurality of laser diodes 106 may be wavelength-locked within different, or only partially overlapping, wavelength-locked ranges.

In a similar manner as that described elsewhere herein, each laser diode 106 may be associated with a FAC 108, a SAC 204, and a reflector 206. Accordingly, a FAC 108, a SAC 204, and/or a reflector 206 may be disposed along an optical path of a laser beam 120 emitted by a corresponding laser diode 106. Further, reflectors 206, of the plurality of reflectors 206, that are associated with a particular set of laser diodes 106 (e.g., that comprises a column of laser diodes 106, or to a portion of a column of laser diodes 106 when the column emits laser beams 120 in different directions) may be configured to receive laser beams 120 (e.g., emitted by the particular set of laser diodes 106) and to direct the laser beams 120 to a corresponding beam transformation component 304 (e.g., in a similar manner as that described elsewhere herein).

Each beam transformation component 304 may be configured in a similar manner as elsewhere described herein. For example, a particular beam transformation component 304 may be configured to receive a laser beam 120; modify one or more characteristics of the laser beam 120, such as a shape or profile of the laser beam 120, and/or or rotate the laser beam 120 (e.g., by a particular number of degrees, such as 90 degrees); and to direct the laser beam 120 to a corresponding transform lens 110. Accordingly, each beam transformation component 304 may receive, modify and/or rotate, and direct laser beams 120 to a corresponding transform lens 110.

Each transform lens 110 may be configured in a similar manner as elsewhere described herein. Accordingly, each first transform lens 110 may be configured to receive, transform, and direct laser beams 120 to a corresponding grating 112.

Each grating 112 may be configured in a similar manner as elsewhere described herein. Accordingly, each grating 112 may be configured to receive and combine (e.g., using WBC) laser beams 120 into a single laser beam 122, and to direct the single laser beam 122 to the OC 114, such as via a corresponding reflector 208.

Each reflector 208 may be configured in a similar manner as elsewhere described herein. Accordingly, each reflector 208 may be configured to receive a single laser beam 122 and to direct the single laser beam 122 to the OC 114. Accordingly, the plurality of reflectors 208 may be configured to provide SBC of a plurality of single laser beams 122 (e.g., after the plurality of gratings 112 provide WBC of respective pluralities of laser beams 120 into the plurality of single laser beams 122).

The OC 114 may be configured in a similar manner as elsewhere described herein. Accordingly, the OC 114 (e.g., respective portions of the OC 114) may be configured to receive respective single laser beams 122 from the plurality of gratings 112 (e.g., as spatially combined single laser beams 122). Adjacent respective portions of the OC 114 may be separated by a gap (e.g., in a similar manner as that described elsewhere herein). Further, the OC 114 may be configured to reflect respective first portions of the single laser beams 122 received by the OC 114 back to the plurality of laser diodes 106 (e.g., in a reverse propagation direction via the plurality of reflectors 208, the plurality of gratings 112, the plurality of transform lenses 110, the plurality of beam transformation components 304, the plurality of reflectors 206, the plurality of SACs 204, and/or the plurality of FACs 108). For example, each portion of the OC 114 may be configured to reflect a first portion of a single laser beam 122 that impinges on the portion of the OC 114 back to a plurality of laser diodes 106 that emitted laser beams 120 included in the single laser beam 122. In this way, each laser diode 106 may be wavelength-locked, in a similar manner as that described elsewhere herein. Additionally, or alternatively, as shown in FIG. 4, the OC 114 may be configured to direct respective second portions of the single laser beams 122 out of the optical module 202, such as to the output fiber 212. For example, each portion of the OC 114 may be configured to direct a second portion of a single laser beam 122 that impinges on the portion of the OC 114 to the lens 210.

The lens 210 may be configured in a similar manner as elsewhere described herein. Accordingly, as shown in FIG. 4, the lens 210 may be disposed along an optical path of the respective second portions of the single laser beams 122 (e.g., that is provided by the OC 114) between the OC 114 and the output fiber 212. The lens 210 may be configured to receive the respective second portions of the single laser beams 122 and to direct the respective second portions of the single laser beams 122 to the output fiber 212.

FIG. 4 is provided as an example. Other examples may differ from what is described with regard to FIG. 4.

The foregoing disclosure provides illustration and description, but is not intended to be exhaustive or to limit the implementations to the precise forms disclosed. Modifications and variations may be made in light of the above disclosure or may be acquired from practice of the implementations. Furthermore, any of the implementations described herein may be combined unless the foregoing disclosure expressly provides a reason that one or more implementations may not be combined.

Even though particular combinations of features are recited in the claims and/or disclosed in the specification, these combinations are not intended to limit the disclosure of various implementations. In fact, many of these features may be combined in ways not specifically recited in the claims and/or disclosed in the specification. Although each dependent claim listed below may directly depend on only one claim, the disclosure of various implementations includes each dependent claim in combination with every other claim in the claim set. As used herein, a phrase referring to “at least one of” a list of items refers to any combination of those items, including single members. As an example, “at least one of: a, b, or c” is intended to cover a, b, c, a-b, a-c, b-c, and a-b-c, as well as any combination with multiple of the same item.

No element, act, or instruction used herein should be construed as critical or essential unless explicitly described as such. Also, as used herein, the articles “a” and “an” are intended to include one or more items, and may be used interchangeably with “one or more.” Further, as used herein, the article “the” is intended to include one or more items referenced in connection with the article “the” and may be used interchangeably with “the one or more.” Furthermore, as used herein, the term “set” is intended to include one or more items (e.g., related items, unrelated items, or a combination of related and unrelated items), and may be used interchangeably with “one or more.” Where only one item is intended, the phrase “only one” or similar language is used. Also, as used herein, the terms “has,” “have,” “having,” or the like are intended to be open-ended terms. Further, the phrase “based on” is intended to mean “based, at least in part, on” unless explicitly stated otherwise. Also, as used herein, the term “or” is intended to be inclusive when used in a series and may be used interchangeably with “and/or,” unless explicitly stated otherwise (e.g., if used in combination with “either” or “only one of”). Further, spatially relative terms, such as “below,” “lower,” “bottom” “above,” “upper,” “top,” and the like, may be used herein for ease of description to describe one element or feature's relationship to another element(s) or feature(s) as illustrated in the figures. The spatially relative terms are intended to encompass different orientations of the apparatus, device, and/or element in use or operation in addition to the orientation depicted in the figures. The apparatus may be otherwise oriented (rotated 90 degrees or at other orientations) and the spatially relative descriptors used herein may likewise be interpreted accordingly.

What is claimed is:

1. An optical module comprising:
a stepped structure that includes a plurality of steps;
a plurality of laser diodes;
a plurality of fast axis collimators (FACs);
a transform lens;
a grating; and
an output coupler (OC), wherein:
each step, of the plurality of steps of the stepped structure, is associated with a particular distance, in a lateral direction, from the transform lens that is different than respective distances of other steps of the plurality of steps,
each laser diode, of the plurality of laser diodes, is disposed on a particular step, of the plurality of steps, that is different than the other steps of the stepped structure on which other laser diodes are disposed,
each FAC, of the plurality of FACs, is disposed between a corresponding laser diode, of the plurality of laser diodes, and the transform lens,
the plurality of laser diodes are configured to emit a plurality of laser beams to the plurality of FACs,
the transform lens is configured to receive the plurality of laser beams from the plurality of FACs and to direct the plurality of laser beams to the grating,
the grating is configured to receive the plurality of laser beams from the transform lens, to combine the plurality of laser beams into a single laser beam, and to direct the single laser beam to the OC, and
the OC is configured to receive the single laser beam from the grating and to direct a portion of the of the single laser beam out of the optical module.

2. The optical module of claim 1, wherein the stepped structure is configured to thermally conduct heat away from the plurality of laser diodes.

3. The optical module of claim 1, wherein each step, of the plurality of steps of the stepped structure, is associated with a particular height that is different than respective heights of the other steps of the plurality of steps.

4. The optical module of claim 1, wherein the plurality of laser diodes are broad area laser diodes.

5. The optical module of claim 1, wherein each laser diode, of the plurality of laser diodes, is configured to emit a laser beam that is associated with a particular wavelength, which is different than respective wavelengths of laser beams emitted by other laser diodes of the plurality of laser diodes.

6. The optical module of claim 1, wherein the transform lens is a Fourier transform lens that is configured to converge the plurality of laser beams on the grating.

7. The optical module of claim 1, wherein the transform lens has a focal length, and the grating is positioned at a distance from the transform lens that is equal to the focal length.

8. The optical module of claim 1, wherein the OC is configured to reflect another portion of the single laser beam back to the plurality of laser diodes to cause the plurality of laser diodes to be wavelength-locked.

9. The optical module of claim 8, wherein each laser diode, of the plurality of laser diodes, is wavelength-locked at a particular wavelength that is different than respective wavelengths at which other laser diodes, of the plurality of laser diodes, are wavelength-locked.

10. The optical module of claim 1, wherein the plurality of laser diodes are configured as multiple columns.

11. An optical module comprising:
a stepped structure that includes a plurality of steps;
a plurality of laser diodes;
a transform lens;
a grating; and
an output coupler (OC), wherein:
at least one laser diode, of the plurality of laser diodes, is disposed on each step of the plurality of steps of the stepped structure,
the transform lens is configured to receive a plurality of laser beams emitted by the plurality of laser diodes and to direct the plurality of laser beams to the grating,
the grating is configured to receive the plurality of laser beams from the transform lens, to combine the plurality of laser beams into a single laser beam, and to direct the single laser beam to the OC, and
the OC is configured to receive the single laser beam from the grating and to direct a portion of the of the single laser beam out of the optical module.

12. The optical module of claim 11, wherein the stepped structure is a heatsink.

13. The optical module of claim 11, wherein each step, of the plurality of steps of the stepped structure, is associated with a particular distance, in a lateral direction, from the transform lens that is different than respective distances of other steps of the plurality of steps.

14. The optical module of claim 11, wherein the plurality of laser diodes are broad area laser diodes.

15. The optical module of claim 11, wherein the transform lens has a focal length, and the grating is positioned at a distance from the transform lens that is equal to the focal length.

16. An optical module comprising:
a stepped structure that includes a plurality of steps;
a plurality of broad area laser diodes (BALs);
a transform lens; and
a grating; wherein:
each step, of the plurality of steps of the stepped structure, is associated with a particular distance, in a lateral direction, from the transform lens that is different than respective distances of other steps of the plurality of steps,
each BAL, of the plurality of BALs, is disposed on a particular step, of the plurality of steps, that is different than other steps of the stepped structure on which other laser diodes are disposed,
the transform lens is configured to receive a plurality of laser beams emitted from the plurality of BALs and to direct the plurality of laser beams to the grating, and
the grating is configured to receive the plurality of laser beams from the transform lens and to combine the plurality of laser beams into a single laser beam.

17. The optical module of claim 16, wherein the transform lens has a focal length, and the grating is positioned at a distance from the transform lens that is equal to the focal length.

18. The optical module of claim 16, wherein the plurality of BALs are configured as multiple columns.

19. The optical module of claim 16, wherein the plurality BALs are configured to emit the plurality of laser beams to the grating via the transform lens,
wherein a length of an optical path of each laser beam, of the plurality of laser beams, to the grating is different than optical path lengths to the grating of other laser beams of the plurality of laser beams.

20. The optical module of claim 16, wherein the stepped structure is configured to thermally conduct heat away from the plurality of BALs.
